(19) United States
(12) Patent Application Publication
(10) Pub. No.: US 2024/0329122 A1
(43) Pub. Date: Oct. 3, 2024

(54) DEVICE UNDER TEST (DUT) STRUCTURES FOR VOLTAGE CONTRAST (VC) DETECTION OF CONTACT OPENS

(71) Applicant: Intel Corporation, Santa Clara, CA (US)

(72) Inventors: Sairam SUBRAMANIAN, Portland, OR (US); Amit PALIWAL, Hillsboro, OR (US); Xiao WEN, Beaverton, OR (US); Dipto THAKURTA, Portland, OR (US)

(21) Appl. No.: 18/128,617

(22) Filed: Mar. 30, 2023

(51) Int. Cl. G01R 31/28

(52) U.S. Cl. CPC G01R 31/2884

(57) ABSTRACT

A device under test (DUT) structure for voltage contrast (VC) detection of contact opens comprises a fin formed along a first direction over a substrate, the fin having a diffusion region, the fin doped to form i) a p-type fin and a p-type diffusion region or ii) an n-type fin and an n-type diffusion region. A trench contact (TCN) segment is along a second direction generally orthogonal to the first direction over the fin and in contact with the diffusion region. A floating gate is generally parallel to the TCN segment over the fin, wherein the floating gate and the TCN segment are not in contact, and the floating gate does not have a via formed thereon.

### TECHNICAL FIELD

Embodiments of the disclosure are in the field of integrated circuits and, in particular, to DUT structures for VC image detection of contact opens.

### BACKGROUND

For the past several decades, the scaling of features in integrated circuits has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for ever-more capacity, however, is not without issue. The necessity to optimize the performance of each device becomes increasingly significant.

Variability in conventional and state-of-the-art fabrication processes may limit the possibility to further extend them into the sub-10 nm range. Consequently, fabrication of the functional components needed for future technology nodes may require the introduction of new methodologies or the integration of new technologies in current fabrication processes or in place of current fabrication processes.

### BRIEF DESCRIPTION OF THE DRAWINGS

FIGS. 1A, 1B and 1C are transmission electron microscope (TEM) images showing cross-sections of various types of contact opens/defects in an integrated circuit structure.

FIG. 1D illustrates a VC image showing a contact open defect in device array, where the dark contact in the device array indicates the contact open.

FIGS. 2A and 2B are diagrams illustrating planar views of DUT structures for inline voltage contrast (VC) detection of contact opens on a p-type epi and an n-type epi, respectively, in accordance with the disclosed embodiments.

FIG. 2C illustrates a cross-section TEM image of a portion of a DUT structure representative of DUT structures in FIGS. 2A and 2B.

FIG. 3A is a diagram showing an example VC image taken of a segment of different types of integrated circuit structures on a wafer.

FIG. 3B shows a histogram of pixel intensity values that can be extracted from the VC image.

FIG. 4A illustrates a layout schematic for detection of TCN segment contact opens using arrays of p-type DUT structures on a wafer.

FIG. 4B illustrates a layout schematic for detection of TCN segment contact opens using arrays of n-type DUT structures on a wafer.

FIG. 5 illustrates a view of a large array of DUT structures to test the yield of a manufacturing process.

FIGS. 6A and 6B are top views of a wafer and dies that include one or more DUT structures for VC image detection of contact opens, in accordance with one or more of the embodiments disclosed herein.

FIG. 7 illustrates a block diagram of an electronic system, in accordance with an embodiment of the present disclosure.

FIG. 8 is a cross-sectional side view of an integrated circuit (IC) device assembly that may include one or more DUT structures for VC image detection of contact opens, in accordance with one or more of the embodiments disclosed herein.

FIG. 9 illustrates a computing device in accordance with one implementation of the disclosure.

### DESCRIPTION OF THE EMBODIMENTS

Device under test (DUT) structures for voltage contrast (VC) detection of contact opens are described. In the following description, numerous specific details are set forth, such as specific material and tooling regimes, in order to provide a thorough understanding of embodiments of the present disclosure. It will be apparent to one skilled in the art that embodiments of the present disclosure may be practiced without these specific details. In other instances, well-known features, such as single or dual damascene processing, are not described in detail in order to not unnecessarily obscure embodiments of the present disclosure. Furthermore, it is to be understood that the various embodiments shown in the Figures are illustrative representations and are not necessarily drawn to scale. In some cases, various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Certain terminology may also be used in the following description for the purpose of reference only, and thus are not intended to be limiting. For example, terms such as “upper”, “lower”, “above”, “below,” “bottom,” and “top” refer to directions in the drawings to which reference is made. Terms such as “front”, “back”, “rear”, and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

Embodiments described herein may be directed to front-end-of-line (FEOL) semiconductor processing and structures. FEOL is the first portion of integrated circuit (IC) fabrication where the individual devices (e.g., transistors, capacitors, resistors, etc.) are patterned in the semiconductor substrate or layer. FEOL generally covers everything up to (but not including) the deposition of metal interconnect layers. Following the last FEOL operation, the result is typically a wafer with isolated transistors (e.g., without any wires).

Embodiments described herein may be directed to back-end-of-line (BEOL) semiconductor processing and structures. BEOL is the second portion of IC fabrication where the individual devices (e.g., transistors, capacitors, resistors, etc.) are interconnected with wiring on the wafer, e.g., the metallization layer or layers. BEOL includes contacts, insulating layers (dielectrics), metal levels, and bonding sites for chip-to-package connections. In the BEOL part of the fabrication stage contacts (pads), interconnect wires, vias and dielectric structures are formed. For modern IC processes, more than 10 metal layers may be added in the BEOL.

Embodiments described below may be applicable to FEOL processing and structures, BEOL processing and structures, or both FEOL and BEOL processing and structures. In particular, although an exemplary processing scheme may be illustrated using a FEOL processing scenario, such approaches may also be applicable to BEOL processing. Likewise, although an exemplary processing scheme may be illustrated using a BEOL processing scenario, such approaches may also be applicable to FEOL processing.

One or more embodiments described herein are directed to structures and architectures for utilizing voltage contrast (VC) to determine if contact metal of integrated circuits is touching epitaxial (epi) source or drain structures, which in turn is grounded to the substrate. Embodiments may include or pertain to manufacturing process technologies for various types of integrated circuits.

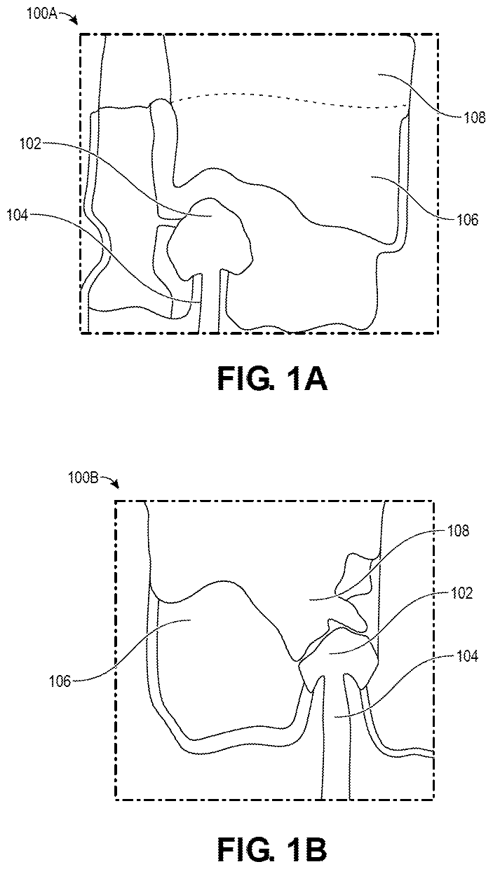

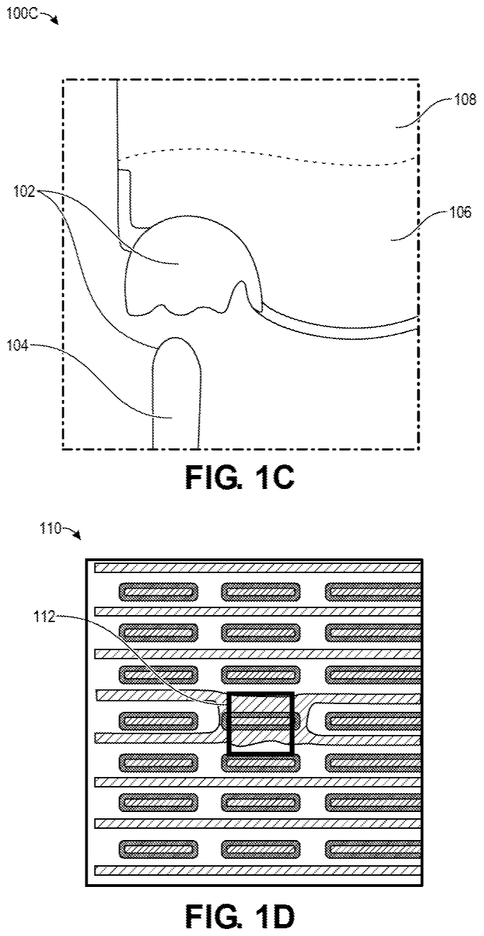

To provide context, FIGS. 1A, 1B and 1C are transmission electron microscope (TEM) images showing cross-sections of various types of contact opens/defects in an integrated circuit structure. The integrated circuit structures 100a, 100b and 100c include epitaxial source/drain structure 102 above a sub-fin 104 of a substrate. A contact silicide 106 and contact metallization 108 is formed over the epitaxial source/drain structure 102, and ideally, the contact silicide 106 should be in contact with the epitaxial source/drain structure 102.

FIG. 1A illustrates a defect in integrated circuit 100a caused by a shallow contact, meaning that the contact silicide 106 is formed too shallow, which forms a gap between it and the epitaxial source/drain structures 102. FIG. 1B illustrates a defect in integrated circuit 100b caused by a missing portion of contact silicide 106. In this case, there is a vertical gap in the contact silicide 106, which causes the contact metallization 108 flow through the gap and touch the epitaxial source/drain structure 102. FIG. 1C illustrates a defect in integrated circuit 100c caused by epi damage, which in this case is caused by a noncontiguous epitaxial source/drain structure 102 to the underlying fin 104. The defects described above can be described as contact opens or shorts.

Successful inline detection of epitaxial silicon to contact metal opens is notoriously difficult. Inline detection of contact opens typically fails since contact opens are buried defects that occur post contact metallization. As these defects are not detectable top down, the defects are typically not discovered until fabrication is complete and tested. For example, processes have had to rely on end of line signals to detect such buried defects. To solve this problem, some destructive Quick turn monitors (QTMs) have been developed that try to etch the epi through the contact space prior to contact metallization to determine if there is an oxide layer that prevents the etch. The QTMs perform unreliably as they are hard to engineer and this approach can only detect contact underetch, not missing contact metal.

In accordance with one or more embodiments described herein, dummy device under test (DUT) structures are used to take advantage of voltage contrast (VC) mode for the detection of electrical opens/shorts between contacts and the epitaxial silicon, preferably shortly after contact metallization is performed. The disclosed embodiments provide inline detection to the difficult problem of epitaxial silicon to contact metal defects/opens and trims 5-6 weeks of yield learning time by not having to run potential skews for solutions to end of line. The VC test is also non-destructive so this can be run on production wafers that can go to end of line thereby minimizing cost and also establishing correlations to known yield signals at end of line. In one embodiment, a DUT structure is fabricated for detection of contact opens on p-type epi. In a second embodiment, a DUT structure is fabricated for detection of contact opens on n-type epi. A wafer of integrated circuits incorporating such dummy DUT structures may exhibit an increase in manufacturing yield.

VC mode is a technique used in semiconductor inspection and analysis to detect defects or irregularities in integrated circuits. VC mode involves applying a voltage to a specific layer of the semiconductor device and observing the resulting contrast in the image produced by an electron microscope. In VC mode, a small voltage is applied to a specific layer of the semiconductor device using a probe. The voltage causes a change in the electrical potential of the layer, which in turn causes changes in the electron beam as it passes through the layer. These changes in the electron beam can be detected by an electron microscope and used to create a VC image of the device. The VC image shows areas where the voltage contrast is high, indicating areas of the device where there may be defects or irregularities.

FIG. 1D, as an example, illustrates a VC image 110 showing a contact open defect in a device array, where a dark contact 112 in the device array indicates the presence of a contact open.

The disclosed embodiments utilize specialized dummy device under test (DUT) structures created for VC analysis that can be used to detect electrical opens/shorts between the contact and the epitaxial silicon. The DUT structures are designed to take advantage of the fact that in VC mode, electron beam tools can distinguish between grounded and floating features. This technique is especially useful in detecting defects that are buried or hidden and are not otherwise accessible for detection through optical metrology. The DUT structures may be fabricated alongside active structures on a test wafer and the wafer is then examined in VC mode to identify defects between the contact and the epitaxial silicon. In the resulting VC images, grounded features appear bright whereas floated appear darker under the right polarity.

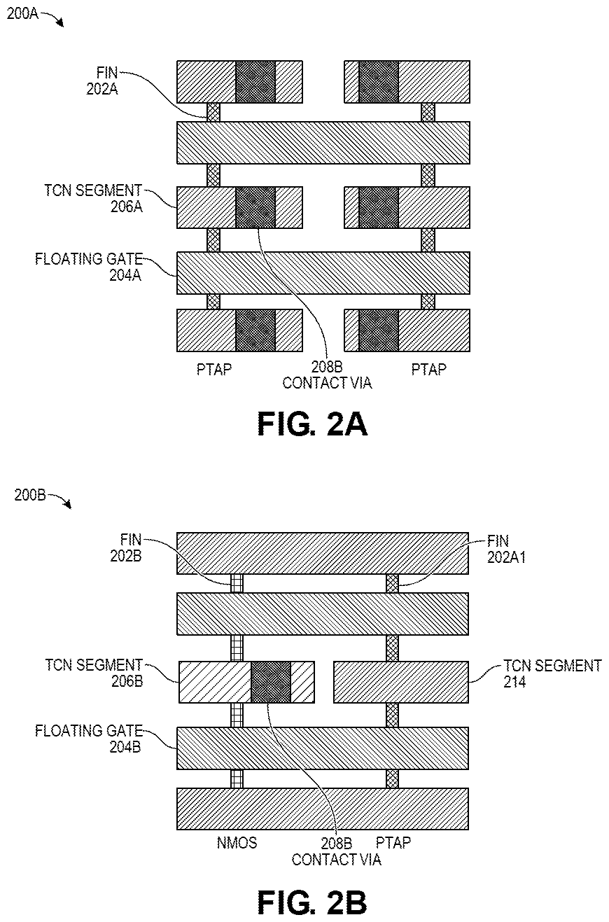

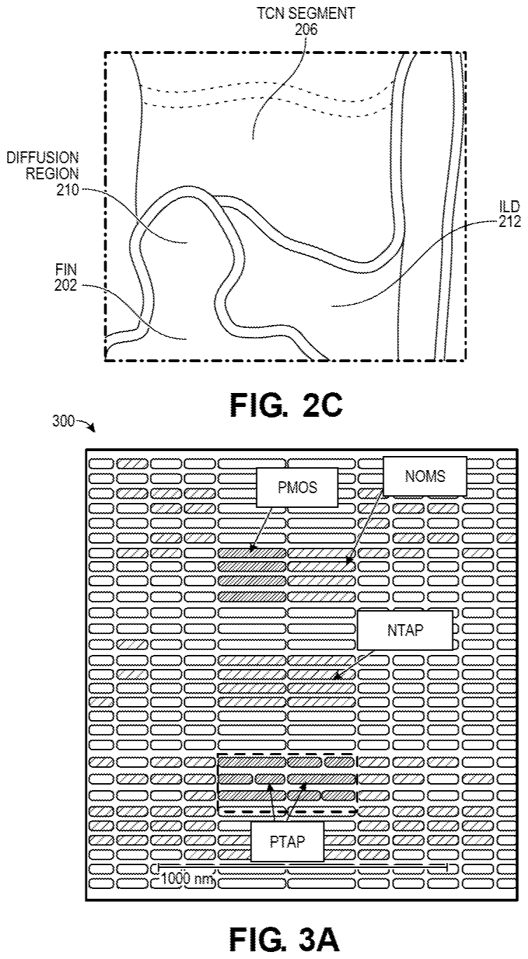

FIGS. 2A and 2B are diagrams illustrating planar views of DUT structures for inline voltage contrast (VC) detection of contact opens on a p-type epi and an n-type epi, respectively, in accordance with the disclosed embodiments. The DUT structures 200a and 200b include a fin 202a/202b formed along a first direction over a substrate (not shown) and the fin 202a/202b includes a diffusion region 210. The diffusion region 210 or epi layer is not visible in this view but is shown in FIG. 2C, which illustrates a cross-section TEM image of a portion of DUT structure 200 that is representative of DUT structures 200a and 200b. Diffusion region 210 comprises a 1D diffusion, which includes a single fin for FinFET devices, and refers to the diffusion of dopant atoms in one dimension only, typically in the vertical direction of the device to form either a p-type fin and a p-type diffusion region or an n-type fin and an n-type diffusion region. The dopant atoms are diffused only in the vertical direction of the fin, resulting in a concentration profile that varies only along the vertical direction. This type of diffusion is used to create a heavily doped source and drain region in the fin.

Referring to FIGS. 2A, 2B, and 2C, in embodiments an interlayer dielectric (ILD) 212 covers the substrate (not shown) from which the fin 202 is formed. Trench openings are etched in the ILD 212 and are filled with contact silicide and metallization to form a trench contact (TCN) segment 206a/206b (collectively referred to as TCN segment 206). The TCN segment 206a/206b is formed along a second direction generally orthogonal to the first direction over the fin 202a/202b and in contact with the diffusion region 210, as shown in FIG. 2C. In embodiments, the TCN segment 206a/206b is formed with a minimum allowed TCN length for a particular technology node, e.g., the smallest TCN feature in an integrated circuit structure product. The advantage of using the minimum allowed TCN length is that it enables localization to one unique epitaxial Si-contact metal interface. So one segment would equal to one defect which helps in yield learning as well as fault isolation and failure analysis.

Referring to FIGS. 2A and 2B, a floating gate 204a/204b is formed generally parallel to the TCN segment 206a/206b. Because the DUT structures 200a and 200b are dummy devices, the floating gate 204a/204b and the TCN segment 206a/206b are not in contact with one another, and the floating gate 204a/204b does not have a via formed thereon. However, a contact via 208a/208b may be optionally formed on the TCN segment 206a/206b, which is useful when there is a desire to inspect the DUT structure 200a/200b from a via layer formed over DUT structure 200a/200b.

Referring to FIG. 2A, the DUT structure 200a for VC detection of contact opens on a p-type diffusion region or epi is shown. The TCN segment 200a is minimum length and formed on a 1D p-type diffusion and is in contact with only one p-type epi. The DUT structure 200a can be referred to as a p-type DUT structure. In one embodiment, the diffusion region 210 is a PTAP structure that comprises PMOS outside of an n-well in a p-type substrate, which results in improved VC signals.

Referring to FIG. 2B showing the DUT structure 200b for VC detection of contact opens on an n-type diffusion region, the TCN segment 200a is minimum length and formed on a 1D n-type diffusion. The DUT structure 200b can be referred to as an n-type DUT structure. In the case of n-type diffusion, the TCN segment 200b is still in contact with only one n-type epi. However, n-type silicon does not naturally appear bright in VC images. Therefore, n-type DUT structure 200b further includes a neighboring TCN segment 214 that is connected by one or more floating gates 204b to a PTAP structure comprising a p-type fin 202al adjacent to the TCN segment 200b. Conduction through n-type DUT structure 200b flows from the n-type TCN contact 206b across the n-type fin 202b through the floating gate 204b to the neighboring connected to PTAP structure, and then through the PTAP. The functionality of the p-type fin 202al in the PTAP structure is to provide electrons to the n-type fin 202b so that opens can be detected in the TCN segment 206b. In VC mode, the PTAP structure generates bright regions in the resulting VC image. Although the PTAP structure is shown comprising only one p-type fin 202al, in other embodiments, the PTAP structure may comprises multiple p-type fins.

In both DUT structures 200a/200b, process corners are stretched by using a TCN segment that is of minimum length on only one epi. This allows for quicker fault isolation as the exact TCN-epi interface that is failing is known. The DUT structures 200a/200b provide inline detection of contact opens, which are difficult to detect and shaves 5-6 weeks of yield learning time by not having to run potential skews for solutions to end of line. The VC test is also non-destructive and thus can be run on production wafers that can go to end of line, thereby minimizing cost and also establishing correlations to known yield signals at end of line.

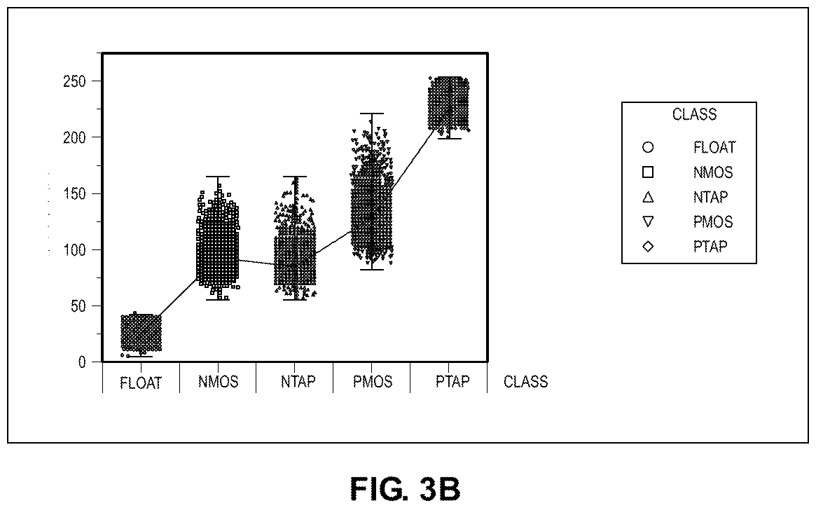

The DUT structures 200a/200b are fabricated on a wafer using the same materials used to fabricate active integrated circuit (IC) structures on the wafer. However, the DUT structures 200a/200b are not electrically connected to other components in the IC structure and serve only for detection of electrical opens/shorts between the TCN segments 206a/206b and the diffusion regions/epitaxial silicon. Subsequent to contact metallization, VC mode is performed. If the TCN segments 206a/206b have no open defects, the TCN segments 206a/206b will appear bright in the resulting VC image, as shown in FIG. 3A.

FIG. 3A is a diagram showing an example VC image taken of a segment of different types of integrated circuit structures on a wafer. And FIG. 3B shows a histogram of pixel intensity values that can be extracted from the VC image. The VC image 300 shows different types of features at different pixel intensity values. The different types of integrated circuit structures include PMOS type contacts or silicon structures, NMOS type contacts or silicon structures, PTAP structures, which are PMOS structures on a PMOS substrate, and NTAP structures, which are NMOS structures on an NMOS substrate. In the histogram of FIG. 3B, a zero pixel intensity is defined as a black and the lowest pixel intensity values generally correspond to a floating gate in the VC image. P-type silicone or substrate have high pixel intensity values. Typically, PTAP structures correspond to the highest (brightest) pixel values in the VC image, followed by PMOS structures. If a segment appears dark in the VC image 300 when it should appear bright, a defect may exists. Cross-section imaging can then be performed on that segment to reveal the defects, as shown in FIGS. 1A-1C.

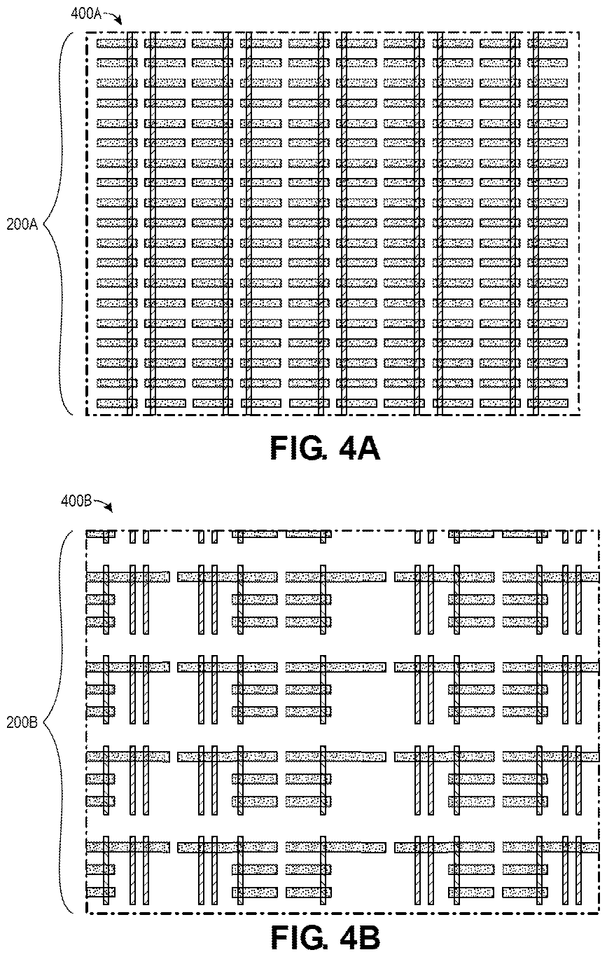

The DUT structures 200a/200b described above can be replicated to form a dummy integrated circuit structure comprising one or more arrays of DUT structures, as shown in FIGS. 4A and 4B. FIG. 4A illustrates a layout schematic 400a for detection of TCN segment contact opens using arrays of p-type DUT structures 200a on a wafer. FIG. 4B illustrates a layout schematic 400b for detection of TCN segment contact opens using arrays of n-type DUT structures 200b on a wafer.

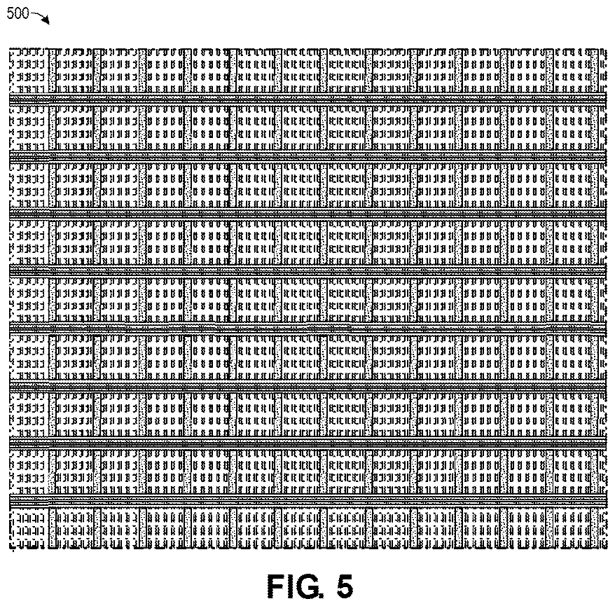

FIG. 5 illustrates a view of a large array 500 of DUT structures 200a and 200b from FIGS. 2A and 2B to test the yield of a manufacturing process. The dummy DUT structures 200a and 200b are interspersed in white spaces between active devices on a wafer. The large arrays of DUT structures may span several 10s/100s of microns with a periodic arrangement of 1D diffusion regions and min length TCNs with floating/dummy gates that are not connected up to routing metal layers. A contact via may land on one or more of the minimum sized TCN segments to enable detection post via formation as well. The DUT structures can be detected by reverse engineering by polishing down to the via and FE stack and examining a planar TEM image.

A method of fabricating a device under test (DUT) structure for voltage contrast (VC) detection of manufacturing defects may include forming a fin along a first direction over a substrate, the fin having a diffusion region, the fin doped to form i) a p-type fin and a p-type diffusion region or ii) an n-type fin and an n-type diffusion region. A trench contact (TCN) segment is formed along a second direction generally orthogonal to the first direction over the fin and in contact with the diffusion region. A floating gate is formed generally parallel to the TCN segment over the fin, wherein the floating gate and the TCN segment are not in contact, and the floating gate does not have a via formed thereon. A VC image is taken and a contact open is determined there when the TCN segment has low (dark) pixel intensity values in the VC image.

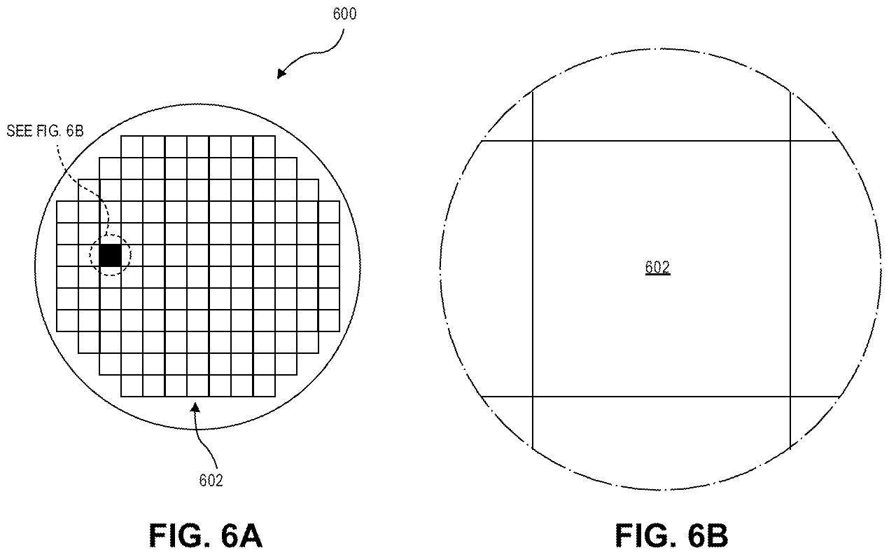

The integrated circuit structures described herein may be included in an electronic device. As an example of one such apparatus, FIGS. 6A and 6B are top views of a wafer and dies that include one or more DUT structures for VC image detection of contact opens, in accordance with one or more of the embodiments disclosed herein.

Referring to FIGS. 6A and 6B, a wafer 600 may be composed of semiconductor material and may include one or more dies 602 having integrated circuit (IC) structures formed on a surface of the wafer 600. Each of the dies 602 may be a repeating unit of a semiconductor product that includes any suitable IC (e.g., ICs including one or more DUT structures for VC image detection of contact opens), such as described above. After the fabrication of the semiconductor product is complete, the wafer 600 may undergo a singulation process in which each of the dies 602 is separated from one another to provide discrete “chips” of the semiconductor product. In particular, structures that include embedded non-volatile memory structures having an independently scaled selector as disclosed herein may take the form of the wafer 600 (e.g., not singulated) or the form of the die 602 (e.g., singulated). The die 602 may include one or more embedded non-volatile memory structures based independently scaled selectors and/or supporting circuitry to route electrical signals, as well as any other IC components. In some embodiments, the wafer 600 or the die 602 may include an additional memory device (e.g., a static random access memory (SRAM) device), a logic device (e.g., an AND, OR, NAND, or NOR gate), or any other suitable circuit element. Multiple ones of these devices may be combined on a single die 602. For example, a memory array formed by multiple memory devices may be formed on a same die 602 as a processing device or other logic that is configured to store information in the memory devices or execute instructions stored in the memory array.

Embodiments disclosed herein may be used to manufacture a wide variety of different types of integrated circuits and/or microelectronic devices. Examples of such integrated circuits include, but are not limited to, processors, chipset components, graphics processors, digital signal processors, micro-controllers, and the like. In other embodiments, semiconductor memory may be manufactured. Moreover, the integrated circuits or other microelectronic devices may be used in a wide variety of electronic devices known in the arts. For example, in computer systems (e.g., desktop, laptop, server), cellular phones, personal electronics, etc. The integrated circuits may be coupled with a bus and other components in the systems. For example, a processor may be coupled by one or more buses to a memory, a chipset, etc. Each of the processor, the memory, and the chipset, may potentially be manufactured using the approaches disclosed herein.

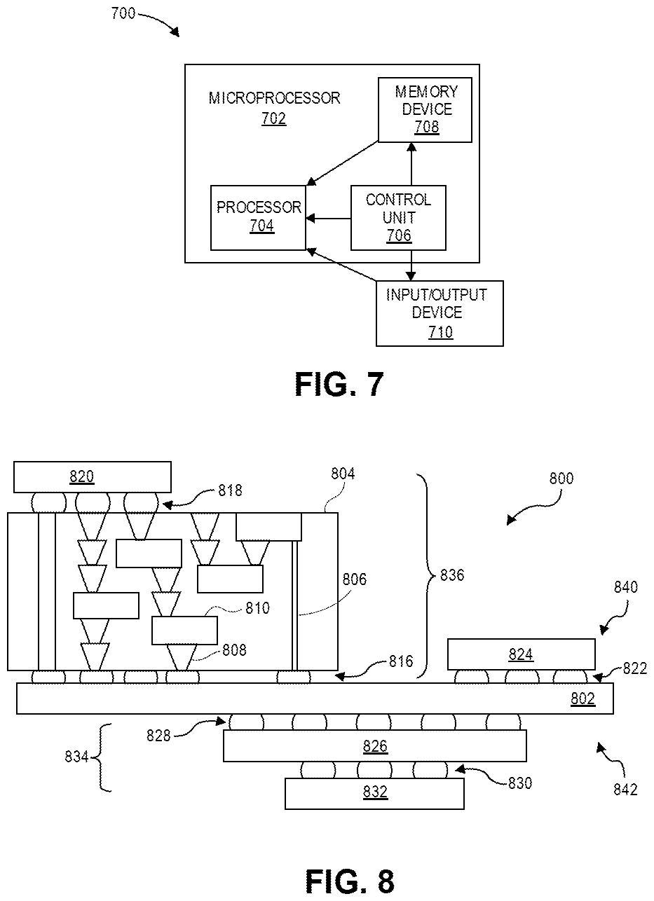

FIG. 7 illustrates a block diagram of an electronic system 700, in accordance with an embodiment of the present disclosure. The electronic system 700 can correspond to, for example, a portable system, a computer system, a process control system, or any other system that utilizes a processor and an associated memory. The electronic system 700 may include a microprocessor 702 (having a processor 704 and control unit 706), a memory device 708, and an input/output device 710 (it is to be appreciated that the electronic system 700 may have a plurality of processors, control units, memory device units and/or input/output devices in various embodiments). In one embodiment, the electronic system 700 has a set of instructions that define operations which are to be performed on data by the processor 704, as well as, other transactions between the processor 704, the memory device 708, and the input/output device 710. The control unit 706 coordinates the operations of the processor 704, the memory device 708 and the input/output device 710 by cycling through a set of operations that cause instructions to be retrieved from the memory device 708 and executed. The memory device 708 can include a non-volatile memory cell as described in the present description. In an embodiment, the memory device 708 is embedded in the microprocessor 702, as depicted in FIG. 7. In an embodiment, the processor 704, or another component of electronic system 700, includes one or more DUT structures for VC image detection of contact opens, such as those described herein.

FIG. 8 is a cross-sectional side view of an integrated circuit (IC) device assembly that may include one or more DUT structures for VC image detection of contact opens, in accordance with one or more of the embodiments disclosed herein.

Referring to FIG. 8, an IC device assembly 800 includes components having one or more integrated circuit structures described herein. The IC device assembly 800 includes a number of components disposed on a circuit board 802 (which may be, e.g., a motherboard). The IC device assembly 800 includes components disposed on a first face 840 of the circuit board 802 and an opposing second face 842 of the circuit board 802. Generally, components may be disposed on one or both faces 840 and 842. In particular, any suitable ones of the components of the IC device assembly 800 may include a number of DUT structures for VC image detection of contact opens, such as disclosed herein.

In some embodiments, the circuit board 802 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 802. In other embodiments, the circuit board 802 may be a non-PCB substrate.

The IC device assembly 800 illustrated in FIG. 8 includes a package-on-interposer structure 836 coupled to the first face 840 of the circuit board 802 by coupling components 816. The coupling components 816 may electrically and mechanically couple the package-on-interposer structure 836 to the circuit board 802, and may include solder balls (as shown in FIG. 8), male and female portions of a socket, an adhesive, an underfill material, and/or any other suitable electrical and/or mechanical coupling structure.

The package-on-interposer structure 836 may include an IC package 820 coupled to an interposer 804 by coupling components 818. The coupling components 818 may take any suitable form for the application, such as the forms discussed above with reference to the coupling components 816. Although a single IC package 820 is shown in FIG. 8, multiple IC packages may be coupled to the interposer 804. It is to be appreciated that additional interposers may be coupled to the interposer 804. The interposer 804 may provide an intervening substrate used to bridge the circuit board 802 and the IC package 820. The IC package 820 may be or include, for example, a die (the die 602 of FIG. 6B), or any other suitable component. Generally, the interposer 804 may spread a connection to a wider pitch or reroute a connection to a different connection. For example, the interposer 804 may couple the IC package 820 (e.g., a die) to a ball grid array (BGA) of the coupling components 816 for coupling to the circuit board 802. In the embodiment illustrated in FIG. 8, the IC package 820 and the circuit board 802 are attached to opposing sides of the interposer 804. In other embodiments, the IC package 820 and the circuit board 802 may be attached to a same side of the interposer 804. In some embodiments, three or more components may be interconnected by way of the interposer 804.

The interposer 804 may be formed of an epoxy resin, a fiberglass-reinforced epoxy resin, a ceramic material, or a polymer material such as polyimide. In some implementations, the interposer 804 may be formed of alternate rigid or flexible materials that may include the same materials described above for use in a semiconductor substrate, such as silicon, germanium, and other group III-V and group IV materials. The interposer 804 may include metal interconnects 810 and vias 808, including but not limited to through-silicon vias (TSVs) 806. The interposer 804 may further include embedded devices, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio-frequency (RF) devices, power amplifiers, power management devices, antennas, arrays, sensors, and microelectromechanical systems (MEMS) devices may also be formed on the interposer 804. The package-on-interposer structure 836 may take the form of any of the package-on-interposer structures known in the art.

The IC device assembly 800 may include an IC package 824 coupled to the first face 840 of the circuit board 802 by coupling components 822. The coupling components 822 may take the form of any of the embodiments discussed above with reference to the coupling components 816, and the IC package 824 may take the form of any of the embodiments discussed above with reference to the IC package 820.

The IC device assembly 800 illustrated in FIG. 8 includes a package-on-package structure 834 coupled to the second face 842 of the circuit board 802 by coupling components 828. The package-on-package structure 834 may include an IC package 826 and an IC package 832 coupled together by coupling components 830 such that the IC package 826 is disposed between the circuit board 802 and the IC package 832. The coupling components 828 and 830 may take the form of any of the embodiments of the coupling components 816 discussed above, and the IC packages 826 and 832 may take the form of any of the embodiments of the IC package 820 discussed above. The package-on-package structure 834 may be configured in accordance with any of the package-on-package structures known in the art.

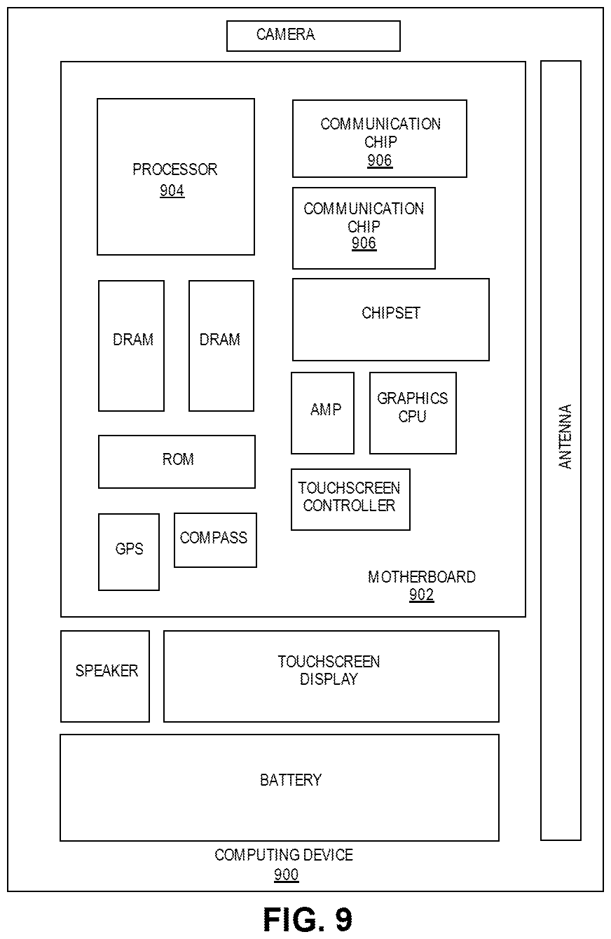

FIG. 9 illustrates a computing device 900 in accordance with one implementation of the disclosure. The computing device 900 houses a board 902. The board 902 may include a number of components, including but not limited to a processor 904 and at least one communication chip 906. The processor 904 is physically and electrically coupled to the board 902. In some implementations the at least one communication chip 906 is also physically and electrically coupled to the board 902. In further implementations, the communication chip 906 is part of the processor 904.

Depending on its applications, computing device 900 may include other components that may or may not be physically and electrically coupled to the board 902. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 906 enables wireless communications for the transfer of data to and from the computing device 900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 906 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 900 may include a plurality of communication chips 906. For instance, a first communication chip 906 may be dedicated to shorter range wireless communications such as Wi-Fi and Bluetooth and a second communication chip 906 may be dedicated to longer range wireless communications such as GPS, EDGE, GPRS, CDMA, WiMAX, LTE, Ev-DO, and others.

The processor 904 of the computing device 900 includes an integrated circuit die packaged within the processor 904. In some implementations of the disclosure, the integrated circuit die of the processor includes one or more DUT structures for VC image detection of contact opens, in accordance with implementations of embodiments of the disclosure. The term “processor” may refer to any device or portion of a device that processes electronic data from registers and/or memory to transform that electronic data into other electronic data that may be stored in registers and/or memory.

The communication chip 906 also includes an integrated circuit die packaged within the communication chip 906. In accordance with another implementation of embodiments of the disclosure, the integrated circuit die of the communication chip includes one or more DUT structures for VC image detection of contact opens, in accordance with implementations of embodiments of the disclosure.

In further implementations, another component housed within the computing device 900 may contain an integrated circuit die that includes one or more DUT structures for VC image detection of contact opens, in accordance with implementations of embodiments of the disclosure.

In various implementations, the computing device 900 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 900 may be any other electronic device that processes data.

Thus, embodiments described herein include DUT structures for VC image detection of contact opens.

The above description of illustrated implementations of embodiments of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

Example embodiment 1: A device under test (DUT) structure for voltage contrast (VC) detection of contact opens comprises a fin formed along a first direction over a substrate, the fin having a diffusion region, the fin doped to form i) a p-type fin and a p-type diffusion region or ii) an n-type fin and an n-type diffusion region. A trench contact (TCN) segment is along a second direction generally orthogonal to the first direction over the fin and in contact with the diffusion region. A floating gate is generally parallel to the TCN segment over the fin, wherein the floating gate and the TCN segment are not in contact, and the floating gate does not have a via formed thereon.

Example embodiment 2: The DUT structure of embodiment 1, wherein the TCN segment has a minimum allowed TCN length for a particular technology node.

Example embodiment 3: The DUT structure of embodiment 1 or 2, further comprising a contact via formed on the TCN segment.

Example embodiment 4: The DUT structure of embodiment 1, 2 or 3, wherein the DUT structure is used for VC contrast detection of contact open defects.

Example embodiment 5: The DUT structure of embodiment 1, 2, 3, or 4, wherein the fin is doped to form the p-type fin and the p-type diffusion region, the p-type diffusion region being a PTAP structure that comprises PMOS outside of an n-well in a p-type substrate.

Example embodiment 6: The DUT structure of embodiment 1, 2, 3, or 4 wherein the fin is doped to form the n-type fin and the n-type diffusion region, the DUT structure further comprising a neighboring TCN segment that is connected via the floating gate to a PTAP structure comprising a p-type fin adjacent to the neighboring TCN segment, the PTAP structure comprising PMOS outside of an n-well in a p-type substrate.

Example embodiment 7: The DUT structure of embodiment 1, 2, 3, 4, 5, or 6, wherein the DUT structure is replicated to form arrays of DUT structures.

Example embodiment 8: The DUT structure of embodiment 1, 2, 3, 4, 5, 6, or 7, wherein the DUT structure is fabricated on a wafer using materials used to fabricate active integrated circuit structures on the wafer.

Example embodiment 9: An integrated circuit (IC) structure for voltage contrast (VC) detection of manufacturing defects comprises a p-type device under test (DUT) structure. The p-type DUT structure comprises a p-type fin along a first direction over a substrate, the p-type fin having a p-type diffusion region. A first trench contact (TCN) segment is along a second direction generally orthogonal to the first direction over the p-type fin and in contact with the p-type diffusion region. A first floating gate is generally parallel to the first TCN segment over the p-type fin, wherein the first floating gate and the first TCN segment are not in contact, and the first floating gate does not have a via formed thereon. An n-type device under test (DUT) structure, comprises an n-type fin along a second direction over a substrate, the n-type fin having a n-type diffusion region. A second trench contact (TCN) segment is along a second direction generally orthogonal to the second direction over the n-type fin and in contact with the n-type diffusion region. A second floating gate is generally parallel to the second TCN segment over the n-type fin, wherein the second floating gate and the second TCN segment are not in contact, and the second floating gate does not have a via formed thereon. A neighboring TCN segment connected via the second floating gate to a PTAP structure comprising a p-type fin adjacent to the neighboring TCN segment, the PTAP structure.

Example embodiment 10: The integrated circuit (IC) structure of embodiment 9, wherein the p-type DUT structure and the p-type DUT structure are replicated to form one or more arrays of DUT structures.

Example embodiment 11: The integrated circuit (IC) structure of embodiment 10, wherein the one or more arrays of DUT structures are interspersed in white spaces between active devices on a wafer.

Example embodiment 12: The integrated circuit (IC) structure of embodiment 11, wherein the DUT structures are not electrically connected to other components in the IC structure and serve only for detection of electrical opens or shorts.

Example embodiment 13: A method of fabricating a device under test (DUT) structure for voltage contrast (VC) detection of manufacturing defects comprises forming a fin along a first direction over a substrate, the fin having a diffusion region, the fin doped to form i) a p-type fin and a p-type diffusion region or ii) an n-type fin and an n-type diffusion region. A trench contact (TCN) segment is formed along a second direction generally orthogonal to the first direction over the fin and in contact with the diffusion region. A floating gate is formed generally parallel to the TCN segment over the fin, wherein the floating gate and the TCN segment are not in contact, and the floating gate does not have a via formed thereon.

Example embodiment 14: The method of embodiment 13, further comprising taking a VC image and determining there is a contact open in the DUT structure when the TCN segment has low pixel intensity values in the VC image.

What is claimed is:

1. A device under test (DUT) structure for voltage contrast (VC) detection of contact opens, comprising:
a fin along a first direction over a substrate, the fin having a diffusion region, the fin doped to form i) a p-type fin and a p-type diffusion region or ii) an n-type fin and an n-type diffusion region;
a trench contact (TCN) segment along a second direction generally orthogonal to the first direction over the fin and in contact with the diffusion region; and
a floating gate generally parallel to the TCN segment over the fin, wherein the floating gate and the TCN segment are not in contact, and the floating gate does not have a via formed thereon.

2. The DUT structure of claim 1, wherein the TCN segment has a minimum allowed TCN length for a particular technology node.

3. The DUT structure of claim 1, further comprising a contact via formed on the TCN segment.

4. The DUT structure of claim 1, wherein the DUT structure is used for VC contrast detection of contact open defects.

5. The DUT structure of claim 1, wherein the fin is doped to form the p-type fin and the p-type diffusion region, the p-type diffusion region being a PTAP structure that comprises PMOS outside of an n-well in a p-type substrate.

6. The DUT structure of claim 1, wherein the fin is doped to form the n-type fin and the n-type diffusion region, the DUT structure further comprising a neighboring TCN segment that is connected via the floating gate to a PTAP structure comprising another p-type fin adjacent to the neighboring TCN segment, the PTAP structure comprising PMOS outside of an n-well in a p-type substrate.

7. The DUT structure of claim 1, wherein the DUT structure is replicated to form arrays of DUT structures.

8. The DUT structure of claim 1, wherein the DUT structure is fabricated on a wafer using materials used to fabricate active integrated circuit structures on the wafer.

9. An integrated circuit (IC) structure for voltage contrast (VC) detection of manufacturing defects, comprising:
a p-type device under test (DUT) structure, comprising:
a p-type fin along a first direction over a substrate, the p-type fin having a p-type diffusion region;
a first trench contact (TCN) segment along a second direction generally orthogonal to the first direction over the p-type fin and in contact with the p-type diffusion region; and
a first floating gate generally parallel to the first TCN segment over the p-type fin, wherein the first floating gate and the first TCN segment are not in contact, and the first floating gate does not have a via formed thereon; and
an n-type device under test (DUT) structure, comprising:
an n-type fin along a second direction over a substrate, the n-type fin having a n-type diffusion region;
a second trench contact (TCN) segment along a second direction generally orthogonal to the second direction over the n-type fin and in contact with the n-type diffusion region;
a second floating gate generally parallel to the second TCN segment over the n-type fin, wherein the second floating gate and the second TCN segment are not in contact, and the second floating gate does not have a via formed thereon; and
a neighboring TCN segment connected via the second floating gate to a PTAP structure comprising a p-type fin adjacent to the neighboring TCN segment, the PTAP structure.

10. The integrated circuit (IC) structure of claim 9, wherein the p-type DUT structure and the p-type DUT structure are replicated to form one or more arrays of DUT structures.

11. The integrated circuit (IC) structure of claim 10, wherein the one or more arrays of DUT structures are interspersed in white spaces between active devices on a wafer.

12. The integrated circuit (IC) structure of claim 11, wherein the DUT structures are not electrically connected to other components in the IC structure and serve only for detection of electrical opens or shorts.

13. A method of fabricating a device under test (DUT) structure for voltage contrast (VC) detection of manufacturing defects, the method comprising:
forming a fin along a first direction over a substrate, the fin having a diffusion region, the fin doped to form i) a p-type fin and a p-type diffusion region or ii) an n-type fin and an n-type diffusion region;
forming a trench contact (TCN) segment along a second direction generally orthogonal to the first direction over the fin and in contact with the diffusion region;
forming a floating gate generally parallel to the TCN segment over the fin, wherein the floating gate and the TCN segment are not in contact, and the floating gate does not have a via formed thereon.

14. The method of claim 13, further comprising taking a VC image and determining there is a contact open in the DUT structure when the TCN segment has low pixel intensity values in the VC image.
